(19) United States
(12) Patent Application Publication
(10) Pub. No.: US 2026/0221976 A1
(43) Pub. Date: Jul. 30, 2026

(54) MULTI-LEVEL PHASE DETECTOR IN A BASEBAND PHASE LOCKED LOOP

(71) Applicant: QUALCOMM Incorporated, San Diego, CA (US)

(72) Inventor: Sang Wook PARK, San Diego, CA (US)

(21) Appl. No.: 19/036,634

(22) Filed: Jan. 24, 2025

(51) Int. Cl. H03L 7/099; H03L 7/107

(52) U.S. Cl. CPC H03L 7/0991; H03L 7/1075

(57) ABSTRACT

A baseband phase-locked loop may have a digitally-controlled oscillator, a frequency divider, a phase detector and a multi-level code generator. The digitally-controlled oscillator may be configured to generate an oscillating signal at a frequency that is controlled by a feedback signal. The frequency divider may be configured to receive the oscillating signal and to produce a plurality of frequency-divided signals. Each frequency-divided signal may be phase shifted with respect to the other frequency-divided signals. The phase detector may be configured to provide a plurality of phase error signals representative of phase errors in the plurality of frequency-divided signals. The multi-level code generator may be configured to generate a gain control signal responsive to the plurality of phase error signals. The gain control signal may be generated based on a signal indicative of gain of the phase detector.

The present disclosure generally relates to phase-locked loops and, more particularly, to controlling phase errors in baseband phase locked loops.

### BACKGROUND

Electronic device technologies have seen explosive growth over the past several years. For example, growth of cellular and wireless communication technologies has been fueled by better communications, hardware, larger networks and more reliable protocols. Electronic devices, including computing devices such as desktop computers, notebook computers, tablet computers, smartphones, wearable devices like a smartwatch, internet servers, provide information, entertainment, social interaction, security, safety, productivity, transportation, manufacturing, and other services to human users. These various electronic devices depend on wired and wireless communications for many of their functions, including in wireless communication systems and devices that are widely deployed to provide various types of communication content such as voice, video, packet data, messaging, broadcast, and so on.

For example, wireless communication devices may include radio frequency (RF) transceivers and/or many subcircuits configured to support basic RF communication functions and the enhanced communication features needed to support evolving communication standards and protocols, and to satisfy end-user requirements. For example, mobile radio frequency integrated circuits (RFICs) may be implemented using deep sub-micron process nodes to reduce cost and power consumption. Examples of communication standards and protocols include code division multiple access (CDMA) systems, time division multiple access (TDMA) systems, frequency division multiple access (FDMA) systems, and orthogonal frequency division multiple access (OFDMA) systems (e.g., a Long Term Evolution (LTE) system or a New Radio (NR) system).

RF transceivers and other subcircuits may include one or more oscillators and one or more amplifiers. In some implementations, the one or more oscillators may include a phase-locked loop with a voltage-controlled oscillator (VCO) or a digitally-controlled oscillator (DCO) for generating an oscillating signal, which may be used for signal processing during signal transmission and reception.

### SUMMARY

Certain aspects of the disclosure relate to circuits, systems, apparatus, methods and techniques that relate to efficient control of phase errors in phase-locked loops.

In various aspects of the disclosure, a phase-locked loop includes a digitally-controlled oscillator configured to generate an oscillating signal at a frequency that is controlled by a feedback signal, a frequency divider configured to receive the oscillating signal and to produce a plurality of frequency-divided signals, each frequency-divided signal being phase shifted with respect to the other frequency-divided signals, a phase detector configured to provide a plurality of phase error signals representative of phase errors in the plurality of frequency-divided signals, and a multi-level code generator configured to generate a gain control signal responsive to the plurality of phase error signals and to a signal indicative of gain of the phase detector.

In various aspects of the disclosure, an apparatus includes means for generating an oscillating signal, including a digitally-controlled oscillator that is controlled by a feedback signal; means for generating a plurality of frequency-divided signals, each frequency-divided signal being phase shifted with respect to the other frequency-divided signals and is a frequency-divided version of the oscillating signal; means for generating a plurality of phase error signals representative of phase errors in a plurality of frequency-divided signals; and means for generating the feedback signal. the means for generating the feedback signal may include a multi-level code generation circuit configured to generate a gain control signal responsive to the plurality of phase error signals and to a signal indicative of gain of the phase detector, and a digital filter configured to low-pass filter the gain control signal to obtain the feedback signal.

In various aspects of the disclosure, a method for controlling phase error in a phase-locked loop includes generating a plurality of frequency-divided signals, providing a plurality of phase error signals representative of phase errors in the plurality of frequency-divided signals, configuring a gain control signal responsive to the plurality of phase error signals and to a signal indicative of gain of the phase detector, and controlling frequency of the oscillating signal by providing a filtered version of the gain control signal to the digitally-controlled oscillator. Each frequency-divided signal may be phase shifted with respect to the other frequency-divided signals and may further be a frequency-divided version of an oscillating signal received from a digitally-controlled oscillator.

In one aspect, a digital filter may be configured to low-pass filter the gain control signal to obtain the feedback signal. In one example, each frequency-divided signal is phase shifted with respect to the other frequency-divided signals by multiples of a half-cycle of the oscillating signal. In another example, each frequency-divided signal is phase shifted with respect to the other frequency-divided signals by multiples of a full cycle of the oscillating signal. In another example, each frequency-divided signal is phase shifted with respect to the other frequency-divided signals by multiples of a fraction of a cycle of the oscillating signal.

In one aspect, the phase detector is configured to receive a reference clock signal. Each of the phase errors may represent a difference between phase of a corresponding frequency-divided signal and the reference clock signal. The phase detector may include a plurality of flipflops clocked by a reference clock signal. Each flipflop may have an input coupled to one of the plurality of frequency-divided signals.

In one aspect, the gain control signal encodes a multibit code configured to define a frequency of the oscillating signal. The multibit code may be changed by a step value when a phase error is detected in the plurality of frequency-divided signals. The step value may be increased when a magnitude of the phase error increases and equals or exceeds a threshold value. The step value may remain constant when a magnitude of the phase error decreases below the threshold value.

### BRIEF DESCRIPTION OF THE DRAWINGS

FIG. 1 illustrates an example of a radio frequency (RF) transceiver in accordance with an aspect of the disclosure.

FIG. 2 illustrates an example of a phase locked loop (PLL) that may be adapted or configured according to certain aspects disclosed herein.

FIG. 3 illustrates a circuit that includes a phase detector that may be adapted or configured in accordance with certain aspects of the present disclosure.

FIG. 4 illustrates an example of the operation of the PLL shown in FIG. 2.

FIG. 5 illustrates a circuit that includes a phase detector configured in accordance with certain aspects of the present disclosure.

FIG. 6 illustrates a first example of the operation of the phase detector illustrated in FIG. 5.

FIG. 7 illustrates a second example of the operation of the phase detector illustrated in FIG. 5.

FIG. 8 is a flowchart illustrating an example of a method for controlling phase error in a phase-locked loop in accordance with certain aspects of this disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of the invention will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

The terms “computing device” and “mobile device” are used interchangeably herein to refer to any one or all of servers, personal computers, smartphones, cellular telephones, tablet computers, laptop computers, netbooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., read only memory (ROM), random access memory (RAM), flash, etc.), and resources (e.g., timers, voltage regulators, oscillators, etc.), any or all of which may be included in one or more cores.

Memory technologies described herein may be suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

With reference now to the drawings, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. The drawings illustrate certain aspects of this disclosure and should not be considered to limit scope of the disclosure.

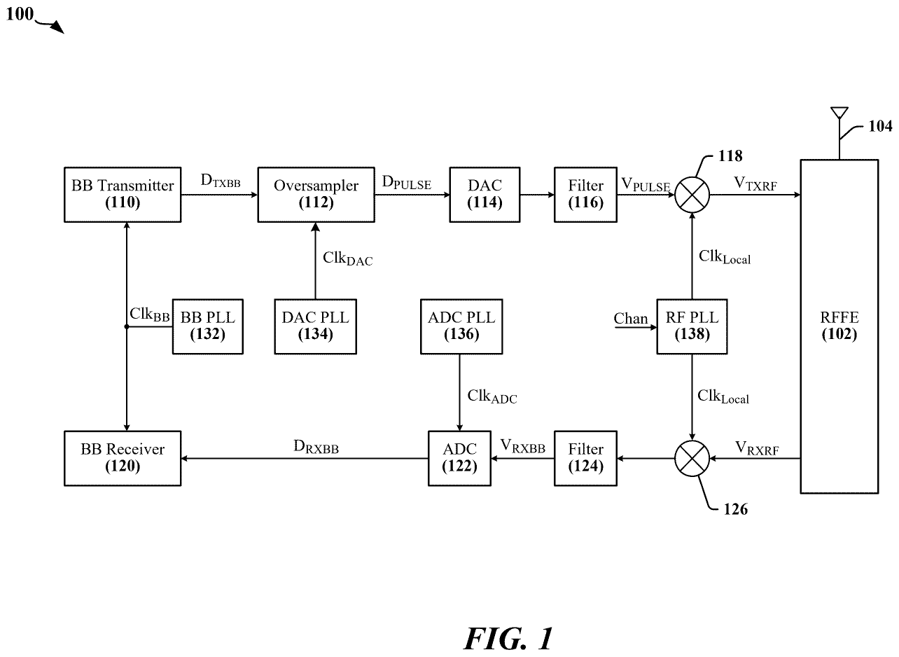

FIG. 1 illustrates an example of a radio frequency (RF) transceiver 100 in accordance with an aspect of the disclosure. The RF transceiver 100 may be configured to transmit and receive signals through a radio frequency front-end (RFFE) circuit 102 and an antenna system 104 that includes at least one antenna and may include a baseband transmitter 110 and a baseband receiver 120. To support signal transmission, the RF transceiver 100 may include an oversampling circuit 112, a digital-to-analog converter (DAC) 114, a transmitter filter 116 and a frequency multiplier 118, which may also be referred to as a frequency upconverter. To support signal reception, the RF transceiver 100 may include a frequency multiplier 126, which may also be referred to as a frequency downconverter, an analog receiver filter 124, and an analog-to-digital converter (ADC) 122. The RF transceiver 100 may include or cooperate with one or more phase-locked loops (PLLs). In the illustrated example, the RF transceiver 100 includes a baseband PLL (BB PLL) 132, a DAC PLL 134, an ADC PLL 136 and a RF PLL 138.

The baseband transmitter 110 may be configured to generate a transmit baseband digital signal D_{TXBB} that encodes data sourced from a media access control (MAC) layer, an application layer, and/or another layer in accordance with timing provided by a baseband clock signal Clk_{BB} generated by the BB PLL 132. The oversampling circuit 112 is configured to generate a transmit digital pulse signal D_{PULSE} based on the transmit baseband digital signal D_{TXBB} in response to a DAC clock signal Clk_{DAC} generated by the DAC oversampling PLL 134. The DAC 114 and the transmitter filter 116 are collectively configured to generate a transmit analog pulse signal V_{PULSE} based on the transmit digital pulse signal D_{PULSE}. The frequency multiplier 118 may be configured to upconvert the frequency of the transmit analog pulse signal V_{PULSE} to generate a transmit RF signal V_{TXRF} based on a local oscillator (LO) clock signal Clk_{Local} generated by the RF PLL 170, which may be further based on a channel signal (CHAN). The RFFE circuit 102 may process the transmit RF signal V_{TXRF} (e.g., power amplify, spectrum mask filter, route via a diplexer/duplexer, and/or other) for wireless transmission to one or more remote wireless devices through the antenna system 104.

The RFFE circuit 102 is also configured to process a signal received from one or more remote wireless devices via the antenna system 104 (e.g., route via a diplexer/duplexer, channel filter, amplify per a low noise amplifier (LNA), and/or other) to generate a received RF signal V_{RXRF}. The frequency multiplier 126 and the analog receiver filter 124 can be collectively configured to frequency down-convert the received RF signal V_{RXRF} into a received baseband analog signal V_{RXBB} based on the LO clock signal Clk_{Local} (or another LO clock signal) generated by the RF PLL 138, which may be based on the CHAN signal. For example, in some transceivers, the same LO clock signal Clk_{Local} may be used to frequency upconvert and down-convert, such as, in a time division multiplexing (TDD) transceiver system, where the transmission of signals is time multiplexed with the reception of signals. In other transceivers, a first LO clock signal Clk_{Local_1} may be used to frequency upconvert and a second LO clock signal Clk_{Local_2} may be used to frequency down-convert, such as, in a frequency division multiplexing (FDD) system where the transmission and reception of signals occur concurrently using different frequency bands, respectively. The ADC 122 is configured to convert the received baseband analog signal V_{RXBB} into a received baseband digital signal D_{RXBB} in response to an ADC oversampling ratio clock signal Clk_{ADCl} generated by the ADC PLL 136. The baseband receiver 120 may be is configured to process the received baseband digital signal D_{RXBB} in response to the baseband clock Clk_{BB} to generate MAC, application, and/or other layer data.

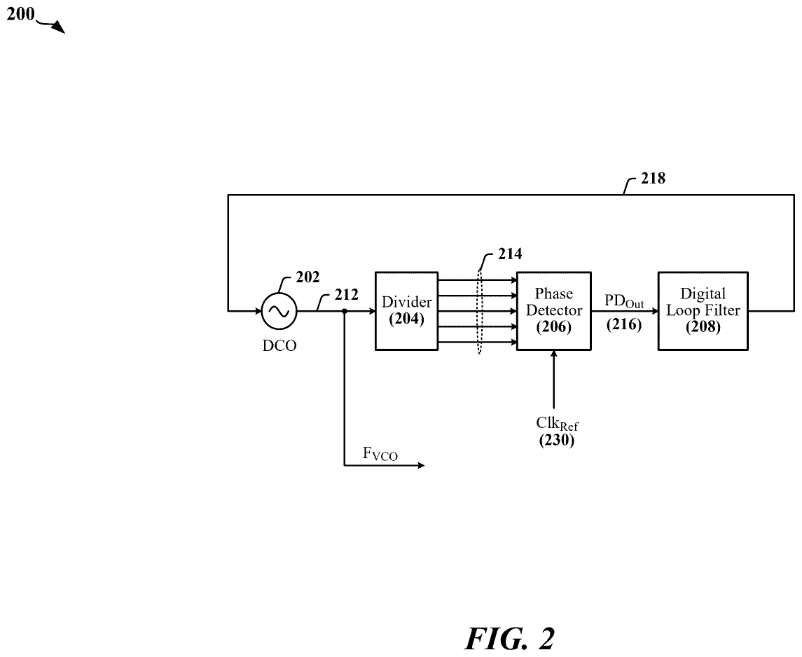

FIG. 2 illustrates an example PLL 200, that may be adapted or configured in accordance with certain aspects of the present disclosure. The PLL 200 includes a digitally-controlled oscillator (the DCO 202), a frequency divider 204, a phase detector 206 and a digital loop filter. In the illustrated example, the DCO 202 is configured to generate a tunable oscillating signal 212 that may be provided as an output of the PLL 200. The oscillating signal 212 is provided at a frequency (F_{VCO}) that can be adjusted or configured using a feedback control signal 218. The period of the oscillating signal 212 may be denoted as T_{VCO} herein. The oscillating signal 212 may be provided to the frequency divider 204. In the illustrated example, the frequency divider 204 can be configured to provide one or more frequency-divided signals 214 that are versions of the oscillating signal 212. The frequency divider 204 may include one or more counters, phase interpolators, delay lines, and other circuits.

The phase detector 206 may be configured to detect and/or signal phase errors between at least one of the frequency-divided signals 214 and a reference clock signal 230. In one example, phase detector 206 compares edges or transitions in the at least one of the frequency-divided signals 214 and edges or transitions in a reference clock signal 230. The reference clock signal 230 may be generated by a reference oscillator such as a crystal oscillator. The phase detector 206 may generate an output signal (e.g., the PD_{Out} signal 216) that represents the phase difference between the frequency-divided signal 214 (or signals) and the reference signal 450.

The PD_{Out} signal 216 is provided to a digital loop filter 208 that outputs the feedback control signal 218. The digital loop filter 208 may be configured to operate as a low-pass filter. In some implementations, the feedback control signal 218 is multibit digital signal that may be used to configure the frequency of the oscillating signal 212 output by the DCO 202. In other implementations, a phase detector may be configured to generate a voltage that represents the phase difference between at least one of the frequency-divided signals 214 and the reference clock signal 230, and an analog low-pass filter may be used to obtain the feedback control signal 218 that serves as a tuning voltage for a voltage controlled oscillator (VCO).

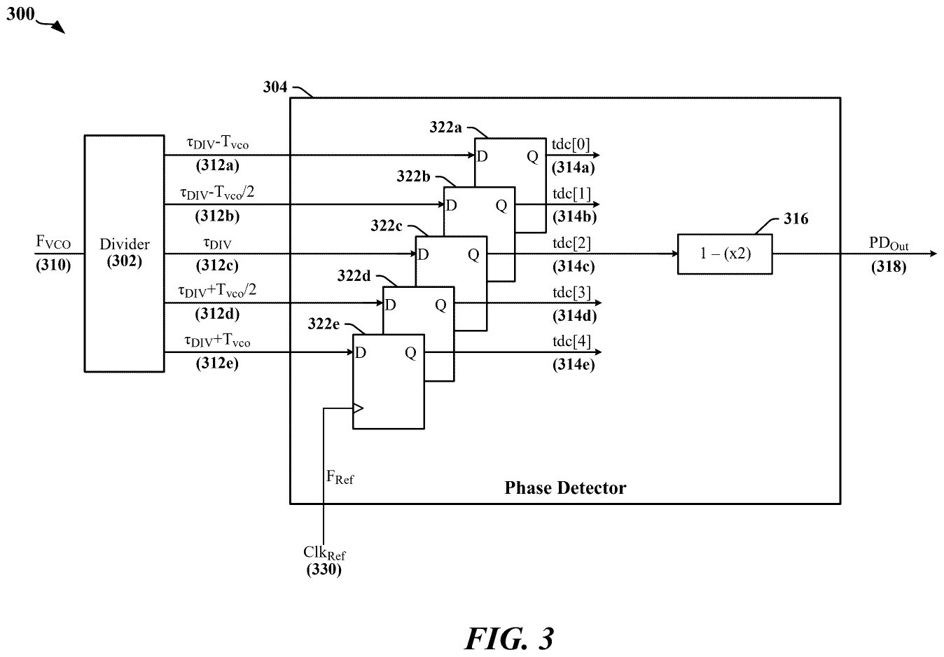

FIG. 3 illustrates a circuit 300 that includes a phase detector 304 that may be adapted or configured in accordance with certain aspects of the present disclosure. The phase detector 304 may correspond in some respects to the phase detector 206 illustrated in FIG. 2. In the illustrated example, a frequency divider 302 is configured to provide frequency-divided signals 312a-312e that are frequency-divided versions of an oscillating signal (i.e., F_{VCO} 310), which may be received by the frequency divider 302 from a DCO or other type of controllable oscillator. The frequency-divided signals 312a-312e may be phase-shifted with respect to one another. In one example, two of the frequency-divided signals 312a, 312b may lead a primary frequency-divided signal 312c, and two of the frequency-divided signals 312d, 312e may lag the primary frequency-divided signal 312c. In the illustrated example, frequency-divided signal 312b leads the primary frequency-divided signal 312c by a half-cycle of F_{VCO} 310, frequency-divided signal 312a leads the primary frequency-divided signal 312c by a full cycle of F_{VCO} 310, frequency-divided signal 312d lags the primary frequency-divided signal 312c by a half-cycle of F_{VCO} 310, and frequency-divided signal 312e lags the primary frequency-divided signal 312c by a full cycle of F_{VCO} 310. The frequency-divided signals 312a-312e may be generated to enable the phase detector 304 to support PLL modes of operation that employ frequency-to-digital conversion. A baseband PLL (see, for example, the BB PLL 132 shown in FIG. 1) operates using the primary frequency-divided signal 312c.

In the illustrated example, the frequency-divided signals 312a-312e are provided to respective flipflops 322a-322e, which are clocked by a reference clock signal (i.e., the Clk_{Ref} signal 330). In certain implementations, the signaling state of the frequency-divided signals 312a-312e is captured by the flipflops 322a-322e as phase error signals 314a-314e (tdc[0]-tdc[4]) that are representative of sampled input phase errors when an edge occurs in the Clk_{Ref} signal 330. In one example, the signaling state of the frequency-divided signals 312a-312e is captured by the flipflops 322a-322e upon occurrence of a rising edge in the Clk_{Ref} signal 330.

In a baseband PLL the phase error signal 314c derived from the center or primary frequency-divided signal 312c provides sign information. The phase error signal 314c may be provided to sign generation logic 316 that converts the single bit binary value of the phase error signal 314c to a digital output (PD_{Out} 318) that has the value PD_{Out}=±1.

With reference also to FIG. 2, a low-pass filtered version of PD_{Out} 318 may be provided as the feedback control signal 218. In one example, DCO 202 may be configured to increase the frequency of oscillating signal 212 when PD_{Out} =+1 and decrease the frequency of oscillating signal 212 when PD_{Out}=−1.

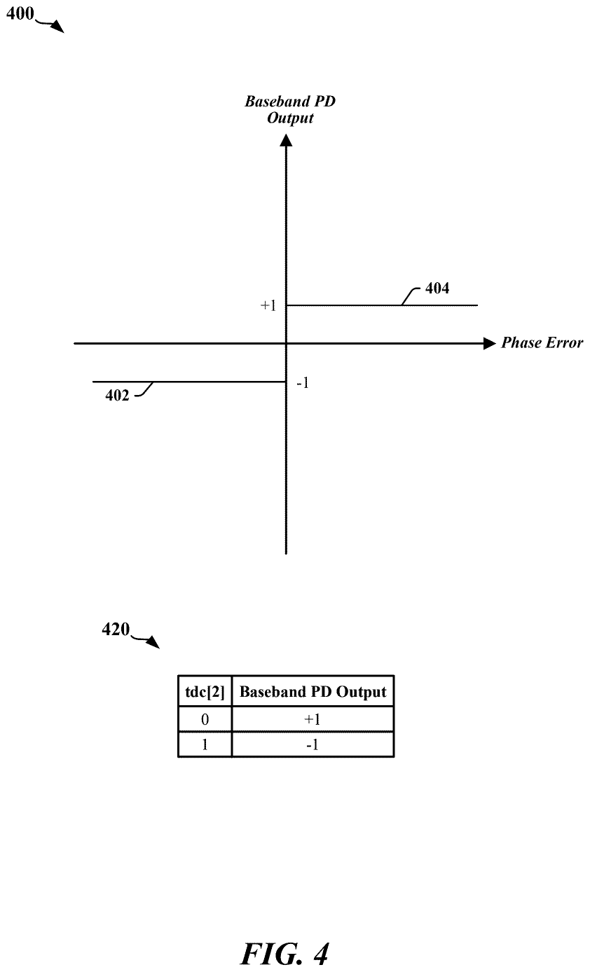

FIG. 4 includes a graph 400 and a table 420 that illustrate an example of the operation of the PLL 200 shown in FIG. 2 when the feedback control signal 218 is derived from PD_{Out} 318 shown in FIG. 3. In one example, PD_{Out}=−1 (as shown by line 402) when the phase error corresponds to a state in which the oscillating signal 212 leads the Clk_{Ref} signal 330, and the DCO 202 may respond to the negative value encoded in PD_{Out} 318 by decreasing the frequency of the oscillating signal 212. In the latter example, PD_{Out}=+1 (as shown by line 404) when the phase error corresponds to a state in which the oscillating signal 212 lags the Clk_{Ref} signal 330, and the DCO 202 may respond to the positive value encoded in PD_{Out} 318 by increasing the frequency of the oscillating signal 212. In conventional systems, adjustments made by the DCO 202 to the frequency of the oscillating signal 212 are incremental. The same step increase or decrease in frequency is applied regardless of the magnitude of phase error, resulting in a decrease in gain of the phase detector 304 as phase error increases. The change in gain occurs due to nonlinearity, whereby the fixed increment size produces in a larger change in frequency relative to size of phase error when phase errors are smaller and smaller change in frequency relative to size of phase error when phase errors are larger. Loop gain of the PLL 200 also decreases, resulting in slower input phase error correction.

Certain aspects of this disclosure relate to a baseband phase-locked loop that can vary the gain of the phase detector based on phase error magnitude. In certain implementations, two or more levels of gain can be provided. The threshold phase error for changing gain may be configured to provide a desired resolution based on magnitude of phase error.

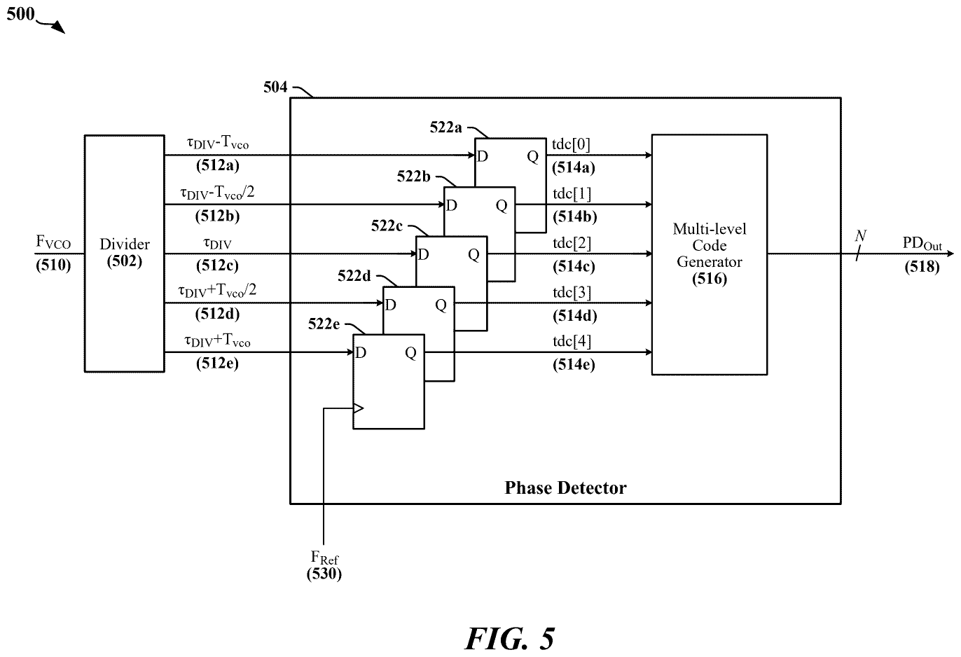

FIG. 5 illustrates a circuit 500 that includes a phase detector 504 that is configured in accordance with certain aspects of the present disclosure. The phase detector 504 may correspond in some respects to the phase detector 206 illustrated in FIG. 2 and the phase detector 304 illustrated in FIG. 3. In the illustrated example, a frequency divider 502 is configured to provide frequency-divided signals 512a-512e that are frequency-divided versions of an oscillating signal i.e., F_{VCO} 510), which may be received by the frequency divider 502 from a DCO or other type of controllable oscillator. The frequency-divided signals 512a-512e may be phase-shifted with respect to one another. In one example, two of the frequency-divided signals 512a, 512b may lead a primary frequency-divided signal 512c, and two of the frequency-divided signals 512d, 512e may lag the primary frequency-divided signal 512c. In the illustrated example, frequency-divided signal 512b leads the primary frequency-divided signal 512c by a half-cycle of F_{VCO} 510, frequency-divided signal 512a leads the primary frequency-divided signal 512c by a full cycle of F_{VCO} 510, frequency-divided signal 512d lags the primary frequency-divided signal 512c by a half-cycle of F_{VCO} 510, and frequency-divided signal 512e lags the primary frequency-divided signal 512c by a full cycle of F_{VCO} 510. The frequency-divided signals 512a-512e may be generated to enable the phase detector 504 to support PLL modes of operation that employ frequency-to-digital conversion.

The illustrated phase detector 504 can use some or all of the frequency-divided signals 512a-512e to provide signals that adjust the frequency of oscillation of F_{VCO} 510 and to configure a gain for the phase detector 504. The frequency-divided signals 512a-512e are provided to respective flipflops 522a-522e, which are clocked by a reference clock signal (i.e., the Clk_{Ref} signal 530). In certain implementations, the signaling state of the frequency-divided signals 512a-512e is captured by the flipflops 522a-522e as phase error signals 514a-514e (tdc[0]-tdc[4]) representative of sampled input phase errors in corresponding frequency-divided signals 512a-512e at an edge in the Clk_{Ref} signal 530. In one example, the signaling state of the frequency-divided signals 512a-512e is captured by the flipflops 522a-522e upon occurrence of a rising edge in the Clk_{Ref} signal 530.

The signaling state of the phase error signals 514a-514e may be used to determine a direction of change in frequency of oscillation of F_{VCO} 510, which may indicate whether frequency of oscillation should be increased or decreased. The signaling state of the phase error signals 514a-514e may be used to determine a magnitude of step changes in a multibit digital value (PD_{Out}) used to control the frequency of oscillation of F_{VCO} 510. The phase error signals 514a-514e may be provided to a multi-level code generator 516 that produces a control signal 518 that encodes a multibit digital value (PD_{Out}). The multi-level code generator 516 may be configured to generate the control signal 518 responsive to the combined signaling state of the phase error signals 514a-514e and a gain signal or flag indicative of gain of the phase detector. In certain implementations, the gain signal or flag is generated and/or maintained by the multi-level code generator 516.

In one example, the multi-level code generator 516 may be implemented using logic circuits that generate the control signal 518 based on signaling state of the phase error signals 514a-514e and previous gain settings for the phase detector 504. The control signal 518 may be provided to a digital filter (e.g., the digital loop filter 208 in FIG. 2). The digital filter may be implemented as a low-pass filter that filters the control signal 518 to generate the feedback control signal 218 that is provided to the DCO 202 and used to configure the frequency of oscillation of F_{VCO} 510.

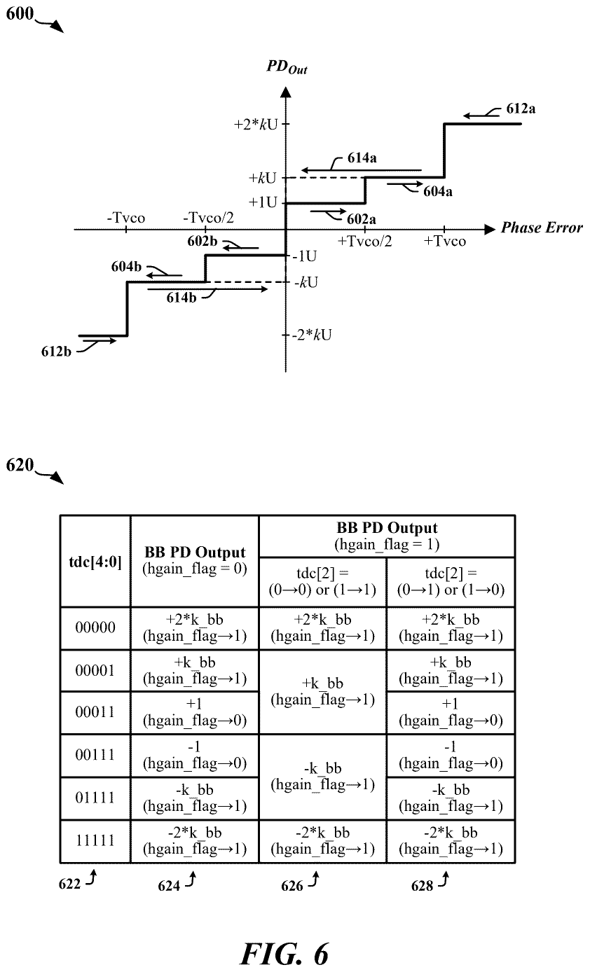

FIG. 6 includes a graph 600 and a truth table 620 that illustrate a first example of the operation of the phase detector 504 illustrated in FIG. 5. The graph 600 plots PD_{Out} step size against phase errors. For the purposes of this disclosure, PD_{Out} step size defines the magnitude of change applied to the value of the PD_{Out} digital value encoded in the control signal 518 when a phase error is detected. PD_{Out} step size can also define the gain of the phase detector 504. Different PD_{Out} step sizes may be applied for different magnitudes of phase error, and PD_{Out} step size may change as certain phase error thresholds are crossed. In some implementations, PD_{Out} step sizes may be configured based on the PD_{Out} step size in effect prior to crossing of a phase error threshold and/or based on whether phase error is increasing or decreasing.

In the illustrated example, a phase error resolution may be defined or configured based on half the period of F_{VCO} 510 (i.e., T_{VCO}/2). In this example, changes in PD_{Out} step size may occur at crossings of one or more phase error thresholds, which may be defined as integer multiples of T_{VCO}/2 (e.g., ±T_{VCO}/2, ±T_{VCO}, ±3*T_{VCO}/2, etc.). In other examples, phase error resolution is configured based on the period of F_{VCO} 510. In some implementations, the gain of the phase detector 504 is increased at each threshold phase error level when the magnitude of the phase error is increasing and decreased at each threshold phase error level when the magnitude of the phase error is decreasing.

In the illustrated example, the gain control employs hysteresis such that PD_{Out} step size is increased at each threshold phase error level when the magnitude of the phase error is increasing and such that PD_{Out} step size is decreased at selected threshold phase error levels when the magnitude of the phase error is decreasing. When F_{VCO} 510 is oscillating at or near a nominal or desired frequency, a minimum PD_{Out} step size may be defined. The minimum PD_{Out} step size may be referred to as the unit PD_{Out} step size (denoted as ‘U’ in the graph 600). The PD_{Out} step size may be changed from the minimum PD_{Out} step size to a step size that is a multiple (k) of the unit PD_{Out} step size when phase error equals or exceeds a first phase error threshold and when magnitude of phase error is increasing as shown by arrows 602a, 602b. In the illustrated example, the first phase error threshold corresponds to ±T_{VCO}/2 and the PD_{Out} step size may be increased at the first phase error threshold to a step size that is a multiple of the unit PD_{Out} step size (i.e., k*U). In one example, k=2. In other examples, k can be assigned any integer or non-integer value. In some implementations, k may be assigned based on the spacing of phase error thresholds, and/or to optimize convergence on nominal or desired frequency. In the illustrated example, the PD_{Out} step size is further increased to 2k*U when the magnitude of the phase error equals or exceeds a second phase error threshold, which corresponds to ±T_{VCO}, and which is increasing as shown by arrows 604a, 604b.

In the illustrated example, hysteresis is provided by decreasing PD_{Out} step size from 2k*U to k*U when the magnitude of the phase error is decreasing, as shown by arrows 612a, 612b, and by refraining from decreasing PD_{Out} step size from k*U when the magnitude of the phase error is decreasing as shown by arrows 614a, 614b. In other examples, hysteresis may be implemented using other phase error thresholds. Different phase error thresholds may be defined for increasing phase error magnitudes than for decreasing phase error magnitudes. Some implementations may disable hysteresis, whereby changes in PD_{Out} step size may occur at the same phase error thresholds regardless of whether phase error magnitude is increasing or decreasing. In some examples, a modified form of hysteresis may be employed, whereby PD_{Out} step size may be changed by different amounts when the magnitude of the phase error is increasing than when the magnitude of the phase error is decreasing.

The phase detector 504 may include or cooperate with a processor, controller, finite state machine or a logic circuit that is configured to implement the truth table 620 provided in FIG. 6. The truth table 620 may be one of multiple truth tables that can be used to configure the operation of the phase detector 504 and/or a PLL that includes the phase detector 504. In one example, a finite state machine or logic circuit may determine when a change in PD_{Out} step size is to occur and the magnitude of the change in PD_{Out} step size based on the signaling state of the phase error signals 514a-514e, which is shown in column 622, and further based on state of operation of the phase detector 504.

The state of operation of the phase detector 504 may be identified by the gain signal or flag (hgain_flag) that may be generated and/or maintained by the multi-level code generator 516 and that may be used to indicate when the PD_{Out} step size has been increased beyond the unit PD_{Out} step size. Column 624 defines the desired or designed PD_{Out} step size for each expected or possible combination of phase error signals 514a-514e bit settings in column 622 when the minimum PD_{Out} step size is in effect. When the PD_{Out} step size is increased, hgain_flag may be set and the desired or designed PD_{Out} step size is defined by column 626 or column 628. Column 626 defines the desired or designed PD_{Out} step size for each expected or possible combination of phase error signals 514a-514e bit settings when an increased PD_{Out} step size is in effect and when the phase error signal 514c derived from the center or primary frequency-divided signal 512c does not change. Column 628 defines the desired or designed PD_{Out} step size for each expected or possible combination of phase error signals 514a-514e bit settings when an increased PD_{Out} step size is in effect and when the phase error signal 514c derived from the center or primary frequency-divided signal 512c changes.

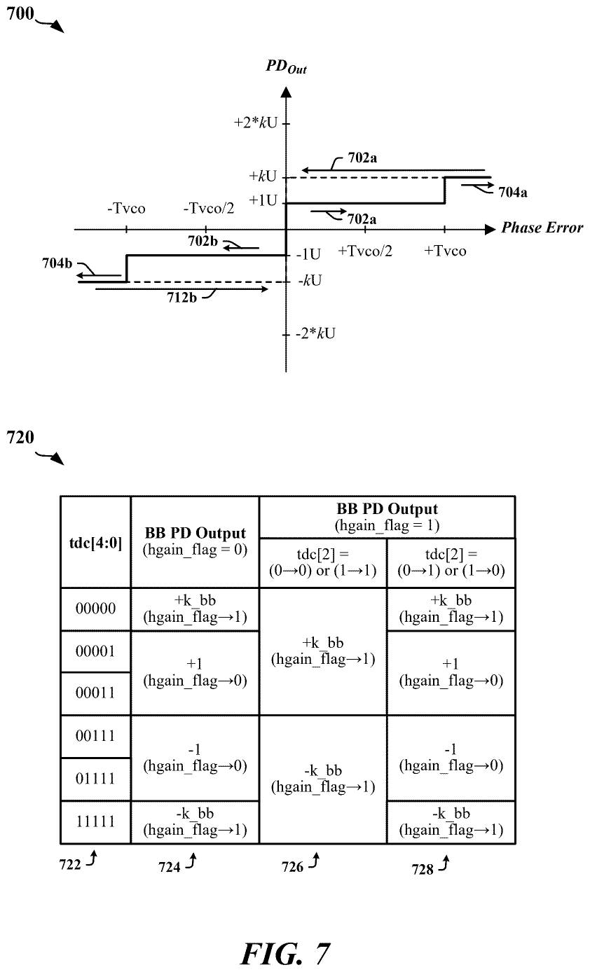

FIG. 7 includes a graph 700 and a truth table 720 that illustrate a second example of the operation of the phase detector 504 illustrated in FIG. 5. The graph 700 plots PD_{Out} step size against phase errors when two PD_{Out} step sizes are provided or available. For the purposes of this disclosure, PD_{Out} step size defines the magnitude of change applied to the value of the PD_{Out} digital value encoded in the control signal 518 when a phase error is detected. PD_{Out} step size can also define the gain of the phase detector 504. Different PD_{Out} step sizes may be applied for different magnitudes of phase error, and PD_{Out} step size may change as certain phase error thresholds are crossed. In some implementations, PD_{Out} step sizes may be configured based on the PD_{Out} step size in effect prior to crossing of a phase error threshold and/or based on whether phase error is increasing or decreasing.

In the illustrated example, a phase error resolution may be defined or configured based on half the period of F_{VCO} 510 (i.e., T_{VCO}/2). In this example, changes in PD_{Out} step size may occur when phase error crosses a selected or configured phase error threshold. The selected or configured phase error threshold may be that defined as an integer multiple of T_{VCO}/2 (e.g., ±T_{VCO}/2, ±T_{VCO}, ±3*T_{VCO}/2, etc.). In other examples, selected or configured phase error threshold may be defined based on the period of F_{VCO} 510. In some implementations, the gain of the phase detector 504 is increased at a selected, predefined or configured threshold phase error level when the magnitude of the phase error is increasing and decreased at each threshold phase error level when the magnitude of the phase error is decreasing.

In the illustrated example, the gain control employs hysteresis such that PD_{Out} step size is increased at the threshold phase error level when the magnitude of the phase error is increasing and such that PD_{Out} step size is decreased at selected threshold phase error levels when the magnitude of the phase error is decreasing. When F_{VCO} 510 is oscillating at or near a nominal or desired frequency, a minimum PD_{Out} step size may be defined. The minimum PD_{Out} step size may be referred to as the unit PD_{Out} step size (denoted as ‘U’ in the graph 700). The PD_{Out} step size may be changed from the minimum PD_{Out} step size to a step size that is a multiple (k) of the unit PD_{Out} step size when phase error equals or exceeds the phase error threshold and when magnitude of phase error is increasing as shown by arrows 702a, 702b. In the illustrated example, the phase error threshold corresponds to ±T_{VCO} and the PD_{Out} step size may be increased at the first phase error threshold to a step size that is a multiple of the unit PD_{Out} step size (i.e., k*U). In one example, k=2. In other examples, k can be assigned any integer or non-integer value. In some implementations, k may be assigned based on the spacing of phase error thresholds, and/or to optimize convergence on nominal or desired frequency.

In the illustrated example, hysteresis is provided by refraining from decreasing PD_{Out} step size from k*U when the magnitude of the phase error is decreasing as shown by arrows 714a, 714b. In other examples, hysteresis may be implemented using other phase error thresholds. Different phase error thresholds may be defined for increasing phase error magnitudes than for decreasing phase error magnitudes. Some implementations may disable hysteresis, whereby changes in PD_{Out} step size may occur at the same phase error thresholds regardless of whether phase error magnitude is increasing or decreasing. In some examples, a modified form of hysteresis may be employed, whereby PD_{Out} step size may be changed by different amounts when the magnitude of the phase error is increasing than when the magnitude of the phase error is decreasing.

The phase detector 504 may include or cooperate with a processor, controller, finite state machine or a logic circuit that is configured to implement the truth table 720 provided in FIG. 7. The truth table 720 may be one of multiple truth tables that can be used to configure the operation of the phase detector 504 and a PLL that includes the phase detector 504. In one example, a finite state machine or logic circuit may determine when a change in PD_{Out} step size is to occur and the magnitude of the change in PD_{Out} step size based on the signaling state of the phase error signals 514a-514e, which is provided in column 722, and further based on state of operation of the phase detector 504.

The state of operation of the phase detector 504 may be identified by the gain signal or flag (hgain_flag) that may be generated and/or maintained by the multi-level code generator 516 and that may be used to indicate when the PD_{Out} step size has been increased beyond the unit PD_{Out} step size. Column 724 defines the desired or designed PD_{Out} step size for each expected or possible combination of phase error signals 514a-514e bit settings in column 722 when the minimum PD_{Out} step size is in effect. When the PD_{Out} step size is increased, hgain_flag may be set and the desired or designed PD_{Out} step size is defined by column 726 or column 728. Column 726 defines the desired or designed PD_{Out} step size for each expected or possible combination of phase error signals 514a-514e bit settings when an increased PD_{Out} step size is in effect and when the phase error signal 514c derived from the center or primary frequency-divided signal 512c does not change. Column 728 defines the desired or designed PD_{Out} step size for each expected or possible combination of phase error signals 514a-514e bit settings when an increased PD_{Out} step size is in effect and when the phase error signal 514c derived from the center or primary frequency-divided signal 512c changes.

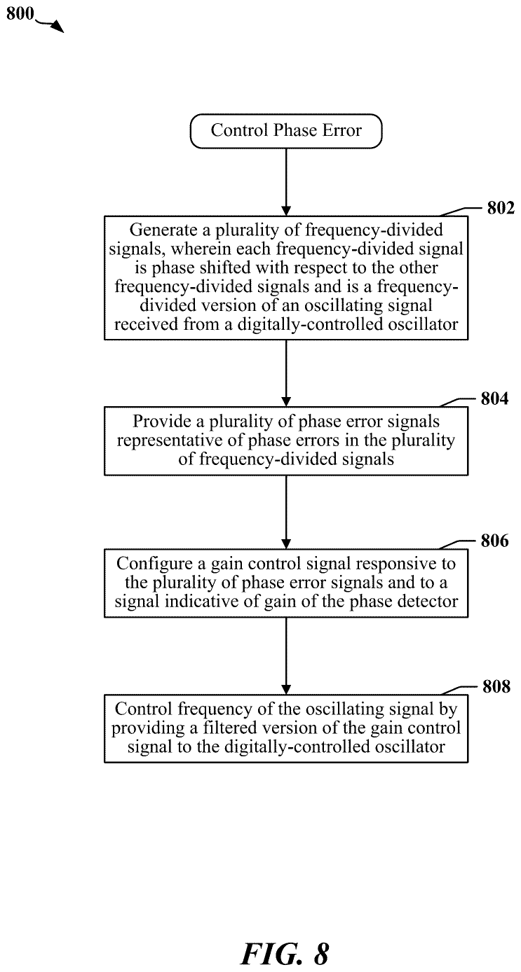

FIG. 8 is a flowchart illustrating an example of a method 800 for controlling phase error in a phase-locked loop in accordance with certain aspects of this disclosure. The method 800 may relate to certain aspects of this disclosure, including aspects related to FIGS. 5-7. For example, the method 800 may be implemented in a PLL such as an adapted version of the PLL illustrated in FIG. 2 or in the phase detector 504 illustrated in FIG. 5. Certain steps or elements of the method 800 may be implemented using a processing circuit that includes a processor, controller and/or finite state machine. Certain steps or elements of the method 800 may be implemented using logic circuits. Certain steps or elements of the method 800 may be implemented using lookup tables to store predefined parameters, such as step sizes, phase error thresholds, and the like.

At block 802, a plurality of frequency-divided signals may be generated. In some implementations, each frequency-divided signal is phase shifted with respect to the other frequency-divided signals. Each frequency-divided signal may be a frequency-divided version derived from an oscillating signal received from a DCO. At block 804, a plurality of phase error signals representative of phase errors in the plurality of frequency-divided signals may be provided to a multi-level code generator or other logic circuit, and/or to the processing circuit, controller or finite state machine.

At block 806, a gain control signal may be configured responsive to the plurality of phase error signals. In one example, the gain control signal may be configured to have an updated value when the plurality of phase error signals indicate presence of a phase error or a change in the magnitude of a previously detected phase error. In another example, the gain control signal may be configured or updated periodically, including in synchronism with edges in a reference signal. Configuration of the gain control signal may be based on state of a signal indicative of gain of the phase detector. The gain of the phase detector may be characterized as a measure of responsiveness to the magnitude of phase errors. For example, the amount of change applied to the gain control signal may be proportionate to some degree to the magnitude of the detected phase error.

At block 808, the frequency of the oscillating signal may be controlled by providing a filtered version of the gain control signal as a feedback signal provided to the DCO. In one example, the feedback signal may encode a value that defines one or more parameters in the DCO. In another example, the feedback signal may modify one or more parameters in the DCO by a step value.

In certain implementations, each of the plurality of frequency-divided signals is phase-shifted with respect to the other frequency-divided signals. Each phase shift may be measured in multiples of a half-cycle of the oscillating signal provided by the DCO. In certain implementations, each of the phase errors represents a difference between phase of a corresponding frequency-divided signal and the reference clock signal.

In certain implementations, the gain control signal encodes a multibit code that is configured to define the frequency of the oscillating signal. The multibit code may be modified by a step value when a phase error is detected. The step value may be modified when a magnitude of the phase error is increasing and equals or exceeds a predefined threshold value. The step value may remain constant when the magnitude of the phase error decreases below the threshold value. Hysteresis is provided when the step value remains constant as the magnitude of the phase error decreases below the threshold value when the phase error is decreasing.

The operational steps in any of the embodiments illustrated herein are described to provide examples. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering. In certain aspects, an apparatus includes means for generating an oscillating signal, means for generating a plurality of frequency-divided signals, means for generating a plurality of phase error signals and means for generating a feedback signal. The means for generating the oscillating signal may include a DCO that is controlled by the feedback signal. Each frequency-divided signal in the plurality of frequency-divided signals may be phase shifted with respect to the other frequency-divided signals in the plurality of frequency-divided signals. Additionally, each frequency-divided signal in the plurality of frequency-divided signals may be a frequency-divided version of the oscillating signal.

The means for generating the feedback signal may include a multi-level code generation circuit configured to generate a gain control signal responsive to the plurality of phase error signals and to a signal indicative of gain of the phase detector, and a digital filter configured to low-pass filter the gain control signal to obtain the feedback signal.

In some implementations, each of the plurality of frequency-divided signals is phase-shifted with respect to the other frequency-divided signals by multiples of a half-cycle of the oscillating signal. In other implementations, each of the plurality of frequency-divided signals is phase-shifted with respect to the other frequency-divided signals by multiples of a full cycle of the oscillating signal. In other implementations, each of the plurality of frequency-divided signals is phase-shifted with respect to the other frequency-divided signals by multiples of a fraction of a cycle of the oscillating signal.

In some implementations, each of the phase errors represents of a difference between phase of a corresponding frequency-divided signal and the reference clock signal.

In certain implementations, the gain control signal encodes a multibit code that is configured to define a frequency of the oscillating signal. The multibit code may be modified by a step value when a phase error is detected. The step value may be increased when a magnitude of the phase error is increasing and equals or exceeds a predefined threshold value. The step value may remain constant when the magnitude of the phase error decreases below the threshold value.

In one aspect, the apparatus may be embodied in a baseband phase-locked loop. The baseband phase-locked loop may have a digitally-controlled oscillator, a frequency divider, a phase detector and a multi-level code generator. The digitally-controlled oscillator may be configured to generate an oscillating signal at a frequency that is controlled by a feedback signal. The frequency divider may be configured to receive the oscillating signal and to produce a plurality of frequency-divided signals. Each frequency-divided signal may be phase shifted with respect to the other frequency-divided signals. The phase detector may be configured to provide a plurality of phase error signals representative of phase errors in the plurality of frequency-divided signals. The multi-level code generator may be configured to generate a gain control signal responsive to the plurality of phase error signals. The gain control signal may be generated based on a signal indicative of gain of the phase detector.

In some embodiments, a digital filter may be configured to low-pass filter the gain control signal to obtain the feedback signal. In one example, each frequency-divided signal is phase shifted with respect to the other frequency-divided signals by multiples of a half-cycle of the oscillating signal. In another example, each frequency-divided signal is phase shifted with respect to the other frequency-divided signals by multiples of a full cycle of the oscillating signal. In another example, each frequency-divided signal is phase shifted with respect to the other frequency-divided signals by multiples of a fraction of a cycle of the oscillating signal.

In some embodiments, the phase detector is configured to receive a reference clock signal. Each of the phase errors may represent a difference between phase of a corresponding frequency-divided signal and the reference clock signal. The phase detector may include a plurality of flipflops clocked by a reference clock signal. Each flipflop may have an input coupled to one of the plurality of frequency-divided signals.

In certain embodiments, the gain control signal encodes a multibit code configured to define a frequency of the oscillating signal. The multibit code may be changed by a step value when a phase error is detected in the plurality of frequency-divided signals. The step value may be increased when a magnitude of the phase error increases and equals or exceeds a threshold value. The step value may remain constant when a magnitude of the phase error decreases below the threshold value.

Some implementation examples are described in the following numbered clauses:
1. A phase-locked loop, comprising: a digitally-controlled oscillator configured to generate an oscillating signal at a frequency that is controlled by a feedback signal; a frequency divider configured to receive the oscillating signal and to produce a plurality of frequency-divided signals, each frequency-divided signal being phase shifted with respect to the other frequency-divided signals; a phase detector configured to provide a plurality of phase error signals representative of phase errors in the plurality of frequency-divided signals; and a multi-level code generator configured to generate a gain control signal responsive to the plurality of phase error signals and to a signal indicative of gain of the phase detector.
2. The phase-locked loop as described in clause 1, further comprising: a digital filter configured to low-pass filter the gain control signal to obtain the feedback signal.
3. The phase-locked loop as described in clause 1 or clause 2, wherein each frequency-divided signal is phase shifted with respect to the other frequency-divided signals by multiples of a half-cycle of the oscillating signal.
4. The phase-locked loop as described in any of clauses 1-3, wherein the phase detector is configured to receive a reference clock signal, and wherein each of the phase errors represents a difference between phase of a corresponding frequency-divided signal and the reference clock signal.
5. The phase-locked loop as described in any of clauses 1-4, wherein the phase detector comprises a plurality of flipflops clocked by a reference clock signal, each flipflop having an input coupled to one of the plurality of frequency-divided signals.
6. The phase-locked loop as described in any of clauses 1-5, wherein the gain control signal encodes a multibit code configured to define a frequency of the oscillating signal.
7. The phase-locked loop as described in clause 6, wherein the multibit code is changed by a step value when a phase error is detected in the plurality of frequency-divided signals, and wherein the step value increases when a magnitude of the phase error increases and equals or exceeds a threshold value.
8. The phase-locked loop as described in clause 7, wherein the multibit code is changed by a step value when a phase error is detected in the plurality of frequency-divided signals, and wherein the step value remains constant when a magnitude of the phase error decreases below the threshold value.
9. An apparatus, comprising: means for generating an oscillating signal, including a digitally-controlled oscillator that is controlled by a feedback signal; means for generating a plurality of frequency-divided signals, wherein each frequency-divided signal is phase shifted with respect to the other frequency-divided signals and is a frequency-divided version of the oscillating signal; means for generating a plurality of phase error signals representative of phase errors in a plurality of frequency-divided signals; and means for generating the feedback signal, including a multi-level code generation circuit configured to generate a gain control signal responsive to the plurality of phase error signals and to a signal indicative of gain of the phase detector, and a digital filter configured to low-pass filter the gain control signal to obtain the feedback signal.
10. The apparatus as described in clause 9, wherein each of the plurality of frequency-divided signals is phase-shifted with respect to the other frequency-divided signals by multiples of a half-cycle of the oscillating signal.
11. The apparatus as described in clause 9 or clause 10, wherein each of the phase errors represents of a difference between phase of a corresponding frequency-divided signal and a reference clock signal.
12. The apparatus as described in any of clauses 9-11, wherein the gain control signal encodes a multibit code that is configured to define a frequency of the oscillating signal.
13. The apparatus as described in clause 12, wherein the multibit code is modified by a step value when a phase error is detected, and the step value is increased when a magnitude of the phase error is increasing and equals or exceeds a predefined threshold value.
14. The apparatus as described in clause 13, wherein the step value remains constant when the magnitude of the phase error decreases below the threshold value.
15. A method for controlling phase error in a phase-locked loop, comprising:
generating a plurality of frequency-divided signals, wherein each frequency-divided signal is phase shifted with respect to the other frequency-divided signals and is a frequency-divided version of an oscillating signal received from a digitally-controlled oscillator; providing a plurality of phase error signals representative of phase errors in the plurality of frequency-divided signals;
configuring a gain control signal responsive to the plurality of phase error signals and to a signal indicative of gain of a phase detector that generates the plurality of phase error signals; and controlling frequency of the oscillating signal by providing a filtered version of the gain control signal to the digitally-controlled oscillator.
16. The method as described in clause 15, wherein each of the plurality of frequency-divided signals is phase-shifted with respect to the other frequency-divided signals by multiples of a half-cycle of the oscillating signal.
17. The method as described in clause 15 or clause 16, wherein each of the phase errors represents a difference between phase of a corresponding frequency-divided signal and a reference clock signal.
18. The method as described in any of clauses 15-17, wherein the gain control signal encodes a multibit code that is configured to define the frequency of the oscillating signal.
19. The method as described in clause 18, further comprising: modifying the multibit code by a step value when a phase error is detected; and increasing the step value when a magnitude of the phase error is increasing and equals or exceeds a predefined threshold value.
20. The method as described in clause 19, wherein the step value remains constant when the magnitude of the phase error decreases below the threshold value.

The present disclosure is provided to enable any person skilled in the art to make or use aspects of the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A phase-locked loop, comprising:
a digitally-controlled oscillator configured to generate an oscillating signal at a frequency that is controlled by a feedback signal;
a frequency divider configured to receive the oscillating signal and to produce a plurality of frequency-divided signals, each frequency-divided signal being phase shifted with respect to the other frequency-divided signals;
a phase detector configured to provide a plurality of phase error signals representative of phase errors in the plurality of frequency-divided signals; and
a multi-level code generator configured to generate a gain control signal responsive to the plurality of phase error signals and to a signal indicative of gain of the phase detector.

2. The phase-locked loop of claim 1, further comprising:
a digital filter configured to low-pass filter the gain control signal to obtain the feedback signal.

3. The phase-locked loop of claim 1, wherein each frequency-divided signal is phase shifted with respect to the other frequency-divided signals by multiples of a half-cycle of the oscillating signal.

4. The phase-locked loop of claim 1, wherein the phase detector is configured to receive a reference clock signal, and wherein each of the phase errors represents a difference between phase of a corresponding frequency-divided signal and the reference clock signal.

5. The phase-locked loop of claim 1, wherein the phase detector comprises a plurality of flipflops clocked by a reference clock signal, each flipflop having an input coupled to one of the plurality of frequency-divided signals.

6. The phase-locked loop of claim 1, wherein the gain control signal encodes a multibit code configured to define a frequency of the oscillating signal.

7. The phase-locked loop of claim 6, wherein the multibit code is changed by a step value when a phase error is detected in the plurality of frequency-divided signals, and wherein the step value increases when a magnitude of the phase error increases and equals or exceeds a threshold value.

8. The phase-locked loop of claim 7, wherein the multibit code is changed by a step value when a phase error is detected in the plurality of frequency-divided signals, and wherein the step value remains constant when a magnitude of the phase error decreases below the threshold value.

9. An apparatus, comprising:
means for generating an oscillating signal, including a digitally-controlled oscillator that is controlled by a feedback signal;
means for generating a plurality of frequency-divided signals, wherein each frequency-divided signal is phase shifted with respect to the other frequency-divided signals and is a frequency-divided version of the oscillating signal;
means for generating a plurality of phase error signals representative of phase errors in a plurality of frequency-divided signals, including a phase detector; and
means for generating the feedback signal, including
a multi-level code generation circuit configured to generate a gain control signal responsive to the plurality of phase error signals and to a signal indicative of gain of the phase detector, and
a digital filter configured to low-pass filter the gain control signal to obtain the feedback signal.

10. The apparatus of claim 9, wherein each of the plurality of frequency-divided signals is phase-shifted with respect to the other frequency-divided signals by multiples of a half-cycle of the oscillating signal.

11. The apparatus of claim 9, wherein each of the phase errors represents of a difference between phase of a corresponding frequency-divided signal and a reference clock signal.

12. The apparatus of claim 9, wherein the gain control signal encodes a multibit code that is configured to define a frequency of the oscillating signal.

13. The apparatus of claim 12, wherein the multibit code is modified by a step value when a phase error is detected, and the step value is increased when a magnitude of the phase error is increasing and equals or exceeds a predefined threshold value.

14. The apparatus of claim 13, wherein the step value remains constant when the magnitude of the phase error decreases below the threshold value.

15. A method for controlling phase error in a phase-locked loop, comprising:
generating a plurality of frequency-divided signals, wherein each frequency-divided signal is phase shifted with respect to the other frequency-divided signals and is a frequency-divided version of an oscillating signal received from a digitally-controlled oscillator;
providing a plurality of phase error signals representative of phase errors in the plurality of frequency-divided signals;
configuring a gain control signal responsive to the plurality of phase error signals and to a signal indicative of gain of a phase detector that generates the plurality of phase error signals; and
controlling frequency of the oscillating signal by providing a filtered version of the gain control signal to the digitally-controlled oscillator.

16. The method of claim 15, wherein each of the plurality of frequency-divided signals is phase-shifted with respect to the other frequency-divided signals by multiples of a half-cycle of the oscillating signal.

17. The method of claim 15, wherein each of the phase errors represents a difference between phase of a corresponding frequency-divided signal and a reference clock signal.

18. The method of claim 15, wherein the gain control signal encodes a multibit code that is configured to define the frequency of the oscillating signal.

19. The method of claim 18, further comprising:
modifying the multibit code by a step value when a phase error is detected; and
increasing the step value when a magnitude of the phase error is increasing and equals or exceeds a predefined threshold value.

20. The method of claim 19, wherein the step value remains constant when the magnitude of the phase error decreases below the threshold value.
